(19) United States
(12) Patent Application Publication
(10) Pub. No.: US 2024/0035144 A1
(43) Pub. Date: Feb. 1, 2024

(54) MASK FRAME, MASK ASSEMBLY, AND METHOD OF MANUFACTURING THE MASK ASSEMBLY

(71) Applicant: Samsung Display Co., Ltd., Yongin-si (KR)

(72) Inventors: HEEMIN PARK, Yongin-si (KR); ARONG KIM, Yongin-si (KR); YOUNGMIN MOON, Yongin-si (KR); YOUNGHO PARK, Yongin-si (KR); AREUM LEE, Yongin-si (KR); SUNGSOON IM, Yongin-si (KR); JUNHO JO, Yongin-si (KR)

(73) Assignee: Samsung Display Co., Ltd., Yongin-si (KR)

(21) Appl. No.: 18/318,832

(22) Filed: May 17, 2023

(30) Foreign Application Priority Data
Jul. 28, 2022 (KR) 10-2022-0093699

(51) Int. Cl. C23C 14/04

(52) U.S. Cl. CPC C23C 14/042

(57) ABSTRACT

A mask frame includes a first surface facing a mask, a second surface extending from a side of the first surface at an angle, a third surface extending from another side of the first surface at an angle to define a frame opening, and a first flow path including a first opening defined through the first surface and extending in a first direction and a second opening extending the first opening, defined through the second surface, and extending in a second direction different from the first direction.

### CROSS REFERENCE TO RELATED APPLICATION

This U.S. non-provisional patent application claims priority under 35 U.S.C. § 119 from Korean Patent Application No. 10-2022-0093699, filed on Jul. 28, 2022 in the Korean Intellectual Property Office, the contents of which are hereby incorporated by reference in its entirety.

### BACKGROUND

### 1. Technical Field

The disclosure relates to a mask frame, a mask assembly, and a method of manufacturing the mask assembly.

### 2. Description of the Related Art

Multimedia devices, such as televisions, mobile phones, tablet computers, navigation devices, and game devices, include a display panel displaying an image. The display panel includes pixels generating the image, and each pixel includes a light emitting element emitting light and a driving element electrically connected to the light emitting element. The display panel is formed by stacking various functional layers on a substrate.

The functional layers of the display panel may be patterned using a mask with an open area extending through the mask. A shape and a location of the patterned functional layers may be controlled by a shape and a location of the open area of the mask.

### SUMMARY

The disclosure provides a mask frame, a mask assembly, and a method of manufacturing the mask assembly capable of preventing a defect in bonding the mask to the mask frame.

The disclosure provides a mask frame, a mask assembly, and a method of manufacturing the mask assembly capable of preventing a substrate from being contaminated due to an organic material during a deposition process.

The disclosure provides a mask frame, a mask assembly, and a method of manufacturing the mask assembly capable of improving a deposition accuracy on a substrate.

Embodiments of the inventive concept provide a mask frame including a first surface facing a mask, a second surface extending from a side of the first surface at an angle; a third surface extending from another side of the first surface at an angle to define a frame opening; and a first flow path comprising a first opening and a second opening extending from the first opening, the first opening defined through the first surface and extending in a first direction, the second opening defined through the second surface and extending in a direction different from the first direction.

The first flow path includes a first redirection portion defined by the first opening and the second opening, and the first redirection portion having a shape in a cross-section perpendicular to the first surface, the shape being selected from bent, curved, cornered and angled.

The shape includes multiple curves.

The mask frame also includes a bonding portion bonded to the mask, and the bonding portion being spaced apart from the first flow path by a predetermined distance.

The first opening is defined between the frame opening and the bonding portion when viewed in a plane parallel to the first surface and is disposed closer to the bonding portion than the frame opening.

The mask frame includes multiple rows of first flow paths the bonding portion is disposed between ones of the rows of the first flow paths.

The first flow path has a section diameter equal to or smaller than about 0.2 mm.

Embodiments of the inventive concept provide a mask assembly including a mask frame comprising a frame opening and a first flow path, the first flow path extending through the mask frame; a mask disposed on the mask frame, and a negative pressure generating part, the first flow path connected to the negative pressure generating part to allow the mask to be adhered to the mask frame, wherein the first flow path comprises a first redirection portion having a first shape in a cross-section perpendicular to a surface facing the mask, the first shape being selected from bent, curved, cornered and angled.

The first shape includes multiple curves.

The first flow path further comprises a first opening extending in a first direction from a first surface of the mask frame that faces the mask; and a second opening extending in a second and different direction from a second surface of the mask frame that faces the negative pressure generating part, the second opening extending from the first opening.

An angle between the first opening and the second opening is greater than about zero (0) degrees and equal to or less than about 90 degrees.

The mask frame also includes a bonding portion bonded to the mask, the bonding portion being spaced apart from the first flow path by a predetermined distance.

The first opening is defined between the frame opening and the bonding portion and is disposed closer to the bonding portion than the frame opening.

The mask frame includes a plurality of rows of first flow paths, the bonding portion being disposed between ones of the rows of the first flow paths.

The mask assembly further includes multiple support sticks disposed on the mask frame.

The support sticks include a second flow path connected to the negative pressure generating part to adhere the mask to the support sticks, the second flow path including a second redirection portion having a second shape in a cross-section perpendicular to the surface facing the mask, the second shape being selected from bent, curved, cornered and angled.

Embodiments of the inventive concept provide a method of manufacturing a mask assembly. The manufacturing method includes providing a mask frame that comprises a frame opening and a first flow path, the first flow bath being spaced-apart from the frame opening; providing a mask; placing the mask on the mask frame; adhering the mask to the mask frame by providing a negative pressure to the first flow path; and bonding the mask to the mask frame.

The method further includes tensioning a third area, wherein the mask comprises a first area, a second area, and the third area, and wherein the first area comprises a plurality of cell areas and corresponds to the frame opening, the second area being disposed adjacent to the first area and between the first area and the third area, the frame opening being aligned with the cell areas upon the tensioning of the third area.

The second area includes a margin area, a bonding area, and a trimming area sequentially arranged in an order from a closest to a farthest from the frame opening and the cell areas, a first opening of the first flow path being disposed at a location corresponding to at least one of the margin area and the trimming area.

The method further includes removing the trimming area and the third area after the bonding of the mask to the mask frame.

According to the mask assembly, the negative pressure is generated in the first flow path disposed within the mask frame to reduce a space between the mask and the mask frame, and thus, the mask is tightly adhered to the mask frame.

According to the mask assembly, the first flow path is provided to include the redirection portion, the redirection portion prevents the organic material from being deposited on the substrate or chamber walls via the first flow path during a deposition process.

According to the mask assembly, the deposition accuracy of the deposition material on the substrate is improved, and thus the substrate and a deposition chamber may be prevented from being contaminated.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 is a view of a deposition apparatus including a mask assembly according to an embodiment of the disclosure;

FIG. 2 is an exploded perspective view of a mask assembly according to an embodiment of the disclosure;

FIG. 3 is a plan view of a mask assembly according to an embodiment of the disclosure;

FIG. 4A is a plan view of a mask frame of FIG. 3;

FIG. 4B is an enlarged view of a portion of the mask frame of FIG. 4A;

FIGS. 5A and 5B are cross-sectional views of mask frames in a direction perpendicular to a first direction according to embodiments of the disclosure;

FIG. 6A is a plan view of a mask frame according to an embodiment of the disclosure;

FIG. 6B is an enlarged view of a portion of the mask frame of FIG. 6A;

FIGS. 7A and 7B are cross-sectional views of mask frames in a direction perpendicular to a first direction according to embodiments of the disclosure;

FIG. 8A is a plan view of a mask frame according to an embodiment of the disclosure;

FIG. 8B is an enlarged view of a portion of the mask frame of FIG. 8A;

FIGS. 9A to 9C are cross-sectional views of mask frames in a direction perpendicular to a first direction according to embodiments of the disclosure;

FIGS. 10A to 10C are cross-sectional views of a first opening in a direction perpendicular to a second direction according to embodiments of the disclosure;

FIGS. 11A to 11F are cross-sectional views of first flow paths in a direction perpendicular to a first direction according to embodiments of the disclosure;

FIG. 12 is an exploded perspective view of a mask assembly according to an embodiment of the disclosure;

FIG. 13 is a plan view of a mask assembly according to an embodiment of the disclosure; and

FIGS. 14A to 14E are views of a method of manufacturing a mask assembly according to an embodiment of the disclosure.

### DETAILED DESCRIPTION OF THE EMBODIMENTS

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms may be only used to distinguish one element from another element. Thus, a first element discussed below could be termed a second element without departing from the teachings of the disclosure. As used herein, the singular forms, “a”, “an” and “the” may be intended to include the plural forms as well, unless the context clearly indicates otherwise.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have a same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so disposed herein.

Spatially relative terms, such as “beneath,” “below,” “under,” “lower,” “on,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Hereinafter, embodiments of the disclosure will be described with reference to accompanying drawings.

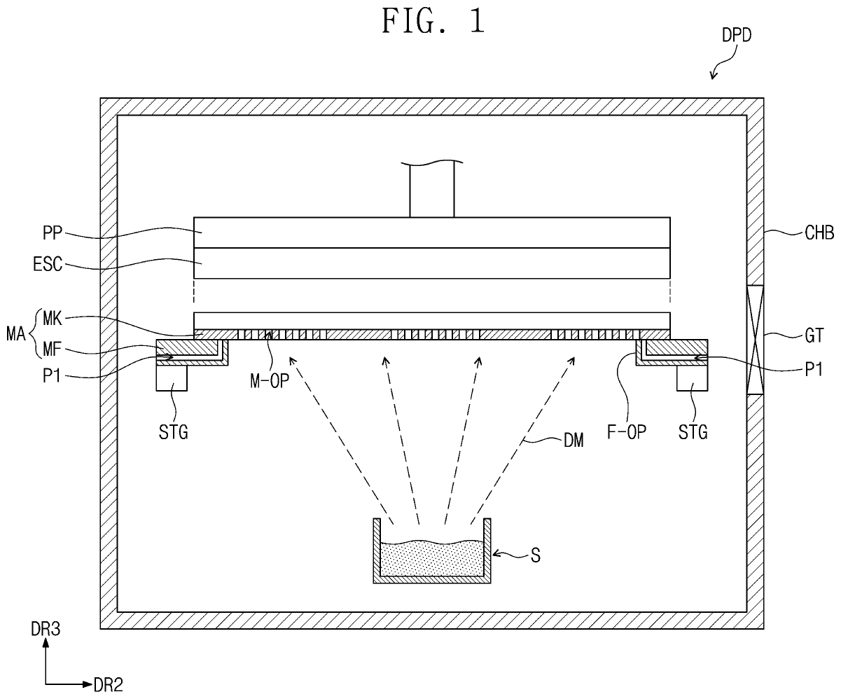

FIG. 1 is a view of a deposition apparatus DPD including a mask assembly MA according to an embodiment of the disclosure.

Referring to FIG. 1, the deposition apparatus DPD may include a chamber CHB, a deposition source S, a stage STG, a moving plate PP, and a mask assembly MA. The deposition source S, the stage STG, the moving plate PP, and the mask assembly MA may be disposed in the chamber CHB.

The chamber CHB may provide a confined space, and a deposition condition of the chamber CHB may be set to a vacuum state. The chamber CHB may include a bottom surface, a ceiling surface, and sidewalls. The bottom surface of the chamber CHB may be substantially parallel to a plane disposed by a first direction DR1 and a second direction DR2. A normal line direction of the bottom surface of the chamber CHB may be substantially parallel to a third direction DR3.

The chamber CHB may include at least one gate GT. The chamber CHB may be opened and closed by the gate GT. A target substrate may be loaded into or unloaded from the chamber CHB through the gate GT formed through the chamber CHB.

The deposition source S may include a deposition material DM. The deposition material DM is a material that is capable of being sublimated or vaporized and may include at least one of an inorganic material and an organic material. The deposition material DM vaporized from the deposition source S may be deposited on the target substrate after passing through a mask MK.

The stage STG may be disposed above the deposition source S. The stage STG may support the mask assembly MA placed thereon. The stage STG may be disposed to overlap a mask frame MF of the mask assembly MA and may not overlap a frame opening F-OP of the mask frame MF. For example, the stage STG may be disposed outside a path through which the deposition material DM is supplied to the target substrate from the deposition source S.

The moving plate PP may align the target substrate on the mask assembly MA. The moving plate PP may move up and down or left and right.

An electrostatic inductor such as an electrostatic chuck may be disposed on the moving plate PP. The electrostatic chuck ESC may include a body formed of a ceramic or the like and an electrode embedded therein. When a voltage is applied to the electrode of the electrostatic chuck ESC, an electrostatic force may be induced. The electrostatic chuck ESC to which the electrostatic force is induced may apply an attractive force by the electrostatic force to a conductive layer included in the mask MK. In the deposition apparatus DPD in which the electrostatic chuck ESC is disposed, the target substrate may be fixed onto the mask assembly MA by the electrostatic force and may be disposed to be tightly adhered to the mask MK. Accordingly, the mask MK may be prevented from sagging, and an accuracy of the deposition process may be improved.

After the deposition material DM is deposited onto the target substrate using the deposition apparatus DPD, the mask assembly MA may be removed.

The mask assembly MA may include the mask MK and the mask frame MF. The target substrate may be disposed on the mask assembly MA. The mask assembly MA may be disposed above the deposition source S in the chamber CHB. The deposition material DM vaporized within the deposition source S may be deposited on the target substrate in a predetermined pattern through multiple mask openings M-OP disposed throughout the mask MK. The mask MK and the mask frame MF will be described in detail later.

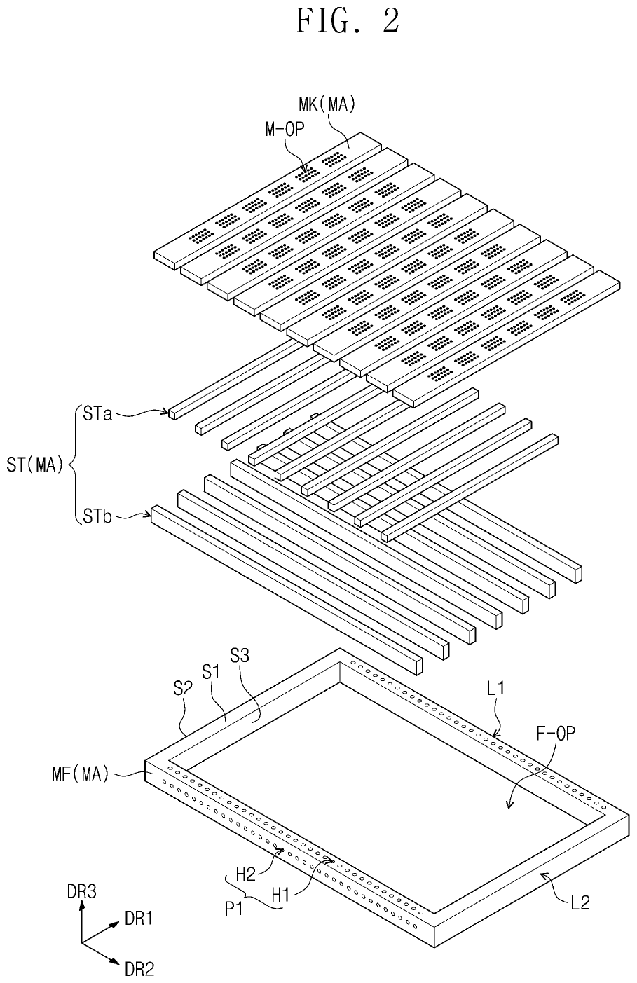

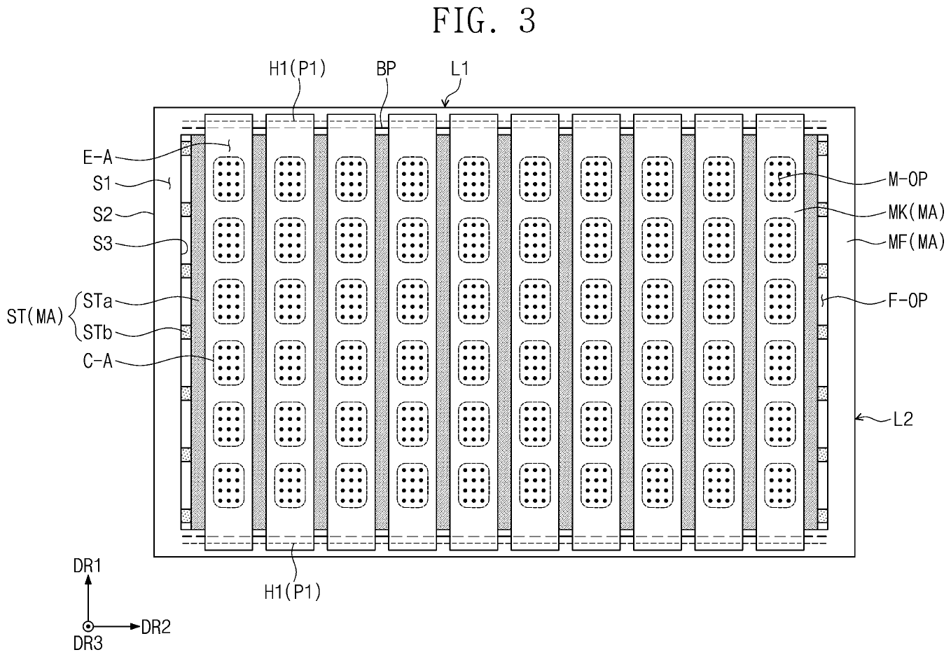

FIG. 2 is an exploded perspective view of the mask assembly MA according to an embodiment of the disclosure, and FIG. 3 is a plan view of the mask assembly MA according to an embodiment of the disclosure.

In the following descriptions, an upper surface of each component may be substantially parallel to a plane disposed by the first direction DR1 and the second direction DR2. A thickness direction of each component may be disposed as the third direction DR3. An upper side (or an upper portion) and a lower side (or a lower portion) of each component described hereinafter may be distinguished from each other with respect to the third direction DR3. However, directions indicated by the first, second, and third directions DR1, DR2, and DR3 may be relative to each other, and thus, the directions indicated by the first, second, and third directions DR1, DR2, and DR3 may be changed to other directions. In the disclosure, the expression “when viewed in a plane” or “on a plane” may mean a state of being viewed in the third direction DR3.

Referring to FIGS. 2 and 3, the mask assembly MA may include the mask MK and the mask frame MF. One mask assembly MA may include multiple masks MK. One mask MK may be provided with multiple mask openings M-OP disposed therethrough. Each of the masks MK may be disposed on the mask frame MF to correspond to the frame opening F-OP of the mask frame MF. In addition, the mask assembly MA may include multiple support sticks ST to support the mask MK.

Each of the masks MK may include multiple cell areas C-A and a peripheral area E-A surrounding the cell areas C-A. The cell areas C-A disposed in each of the masks MK may overlap the frame opening F-OP of the mask frame MF. The mask openings M-OP may be disposed in each of the cell areas C-A and may be arranged spaced apart from each other. The openings M-OP of each of the cell areas C-A may be provided in various shapes and arrangements according to design conditions. The cell areas C-A may be spaced apart from each other with the peripheral area E-A interposed therebetween.

Each of the masks MK may be coupled with the mask frame MF in the peripheral area E-A where the masks MK overlap the mask frame MF.

When viewed in the plane, each of the masks MK may have a quadrangular shape, however, the shape of the mask MK should not be limited thereto or thereby.

The masks MK included in the mask assembly MA may have a same size, however, they should not be limited thereto or thereby. According to an embodiment, some of the masks MK may have different sizes. Sizes of the frame openings F-OP of the mask frame MF may vary depending on the size of the masks MK. The sizes of the masks MK and the frame openings F-OP may vary depending on a size of a deposition target.

In the embodiment, the masks MK may be arranged in the second direction DR2. However, the masks MK may be arranged in the first direction DR1 and/or the second direction DR2 according to the size of the masks MK or the size and number of the frame openings F-OP, and the arrangement of the masks MK should not be limited. The number of the masks MK may vary depending on the target substrate on which the deposition material is deposited or may vary depending on the number of the frame openings F-OP disposed through the mask frame MF.

Referring to FIGS. 2 and 3, the mask frame MF may include first, second, and third surfaces S1, S2, and S3. The first surface S1 may define an upper surface of the mask frame MF. The first surface S1 may be a surface on which the masks MK may be disposed.

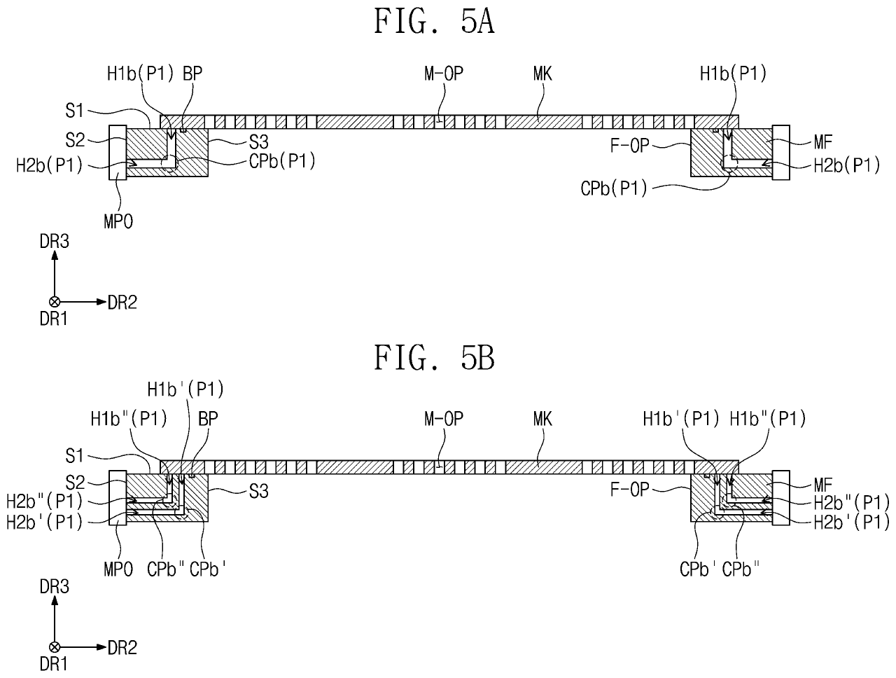

The second surface S2 may extend from a side of the first surface S1 at an angle. The second surface S2 may define an outer side surface of the mask frame MF. The second surface S2 may face a negative pressure generating part MPO described later with reference to FIG. 5A.

The third surface S3 may extend from another side of the first surface S1 at an angle. The third surface S3 may be opposite to the second surface S2 and may define an inner side surface of the mask frame MF. The third surface S3 may also define the frame opening F-OP.

The mask frame MF may have a quadrangular frame shape. In detail, the mask frame MF may include long side portions L1 spaced apart from each other in the first direction DR1 and extending in the second direction DR2 and short side portions L2 spaced apart from each other in the second direction DR2 and extending in the first direction DR1. The long side portions L1 may extend from the short side portions L2 to define the quadrangular frame shape, however, this is merely an example. According to an embodiment, the mask frame MF may be designed to have a variety of shapes and should not be limited.

The mask frame MF may include the upper surface substantially parallel to the plane disposed by the first direction DR1 and the second direction DR2, a lower surface (not shown) opposite to the upper surface, the outer side surface extends from the upper surface and the lower surface, and the inner side surface extends from the upper surface and the lower surface and opposite to the outer side surface to define the frame opening. The mask frame MF may be coupled with the masks MK on the upper surface thereof. The mask frame MF may be coupled with the masks MK by a bonding portion BP, and in the embodiment, the bonding portion BP may be formed on the long side portions L1.

The mask frame according to the embodiment may be provided with at least one flow path P1 (hereinafter, referred to as a first flow path) disposed therein. The first flow path P1 may be disposed at a location adjacent to the bonding portion BP. According to the embodiment, there may be multiple first flow paths P1, and they may be disposed in the long side portions L1 on which the bonding portion BP may be disposed, however, this is merely an example. According to an embodiment, the bonding portion BP may instead be disposed in the short side portions L2, and the first flow path P1 may instead be disposed in the short side portions L2.

There may be multiple rows of first flow paths P1, and because the first opening H1 and the second opening H2 correspond to each first flow path P1, there may be multiple rows of first openings H1 and multiple rows of second openings H2. Each of the first flow paths P1, the first openings H1, and the second openings H2 may be disposed to have a certain pattern, however, they should not be limited thereto or thereby.

The first flow path P1 may also include a redirection portion CP that may be curved, cornered, angled or partially bent on a cross-section perpendicular to the first surface S1, i.e., a cross-section defined by the first direction DR1 and the third direction DR3. The first flow path P1 may include a first opening H1 that perforates the first surface S1, and a second opening H2 that perforates the second surface S2 and extends from the first opening H1. The first opening H1 may extend from the first surface S1 in a first direction, and the second opening H2 may extend from the second surface S2 in a second direction different from the first direction and may also extend from the first opening H1.

Referring to FIGS. 2 and 3, the support stick ST may be disposed between the mask MK and the mask frame MF. The support stick ST may be disposed on the mask frame MF. There may be multiple support sticks ST, and the support sticks ST may be disposed on the mask frame MF and may be spaced apart from each other by a predetermined distance. The mask MK may be disposed on the support sticks ST to prevent mask MK from sagging in a direction in which gravity may be applied, e.g., a direction opposite to the third direction DR3 in the embodiment. In addition, a gap between the mask MK and the mask frame MF may be filled with the support sticks ST, and thus, unwanted deposition of the deposition material DM or the organic material on the substrate via the gap may be prevented.

The support stick ST may include a first stick STa extending in the first direction DR1 and a second stick STb extending in the second direction DR2. The first stick STa may extend in a direction parallel to the short side portions L2 of the mask frame MF, and the second stick STb may extend in a direction parallel to the long side portions L1 of the mask frame MF.

One end of the first stick STa may be disposed in a stick groove (not shown) disposed in one of the long side portions L1 of the mask frame MF, and the other end of the first stick STa may be disposed in a stick groove (not shown) disposed in the other of the long side portions L1 of the mask frame MF. One end of the second stick STb may be disposed in a stick groove (not shown) disposed in one of the short side portions L2 of the mask frame MF, and the other end of the second stick STb may be disposed in a stick groove (not shown) of the other of the short side portions L2 of the mask frame MF. The first stick STa and the second stick STb may be disposed in corresponding stick grooves (not shown) and may be stably coupled to the mask frame MF.

Meanwhile, the first stick STa may be omitted from the mask assembly MA, and thus, the support stick ST may include only the second sticks STb. According to an embodiment, the support stick ST may be omitted in the mask assembly MA, and the disclosure should not be limited.

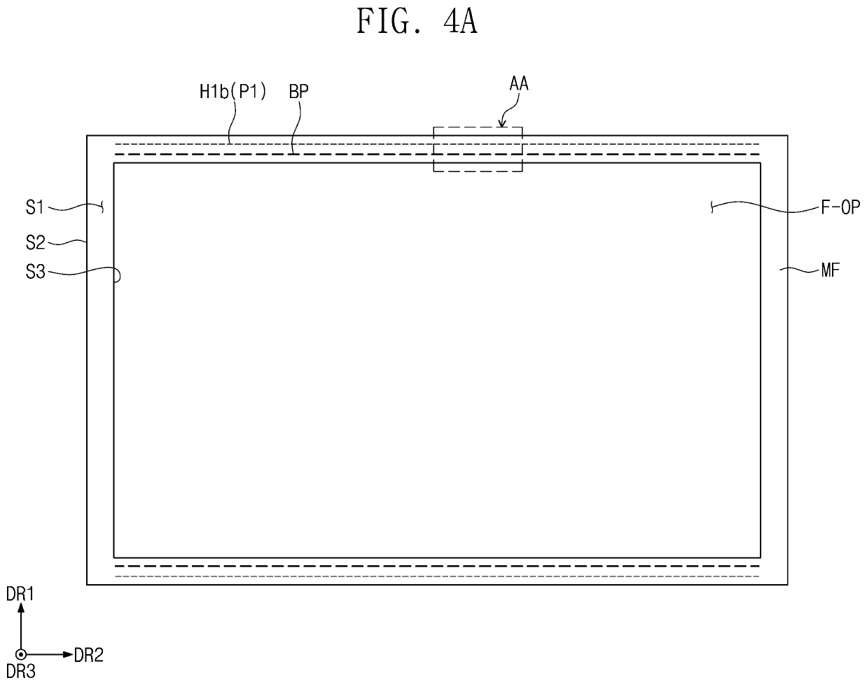

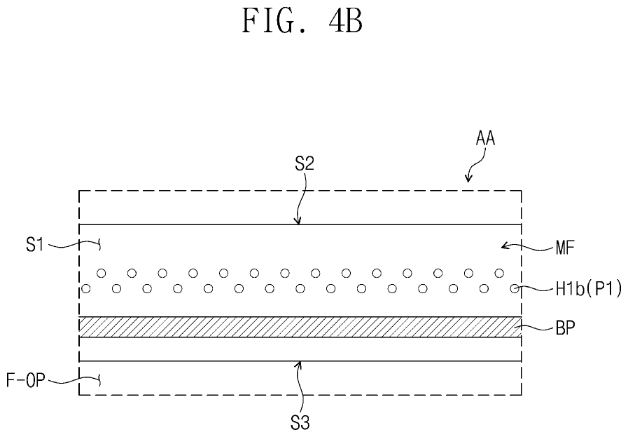

FIG. 4A is a plan view of a mask frame MF according to an embodiment of the disclosure, and FIG. 4B is an enlarged view of portion AA of the mask frame MF of FIG. 4A. FIGS. 5A and 5B are cross-sectional views of mask frames in a direction perpendicular to the first direction DR1 according to embodiments of the disclosure.

The bonding portion BP may be disposed in the mask frame MF and may be coupled with the mask MK. The bonding portion BP may extend in the first direction DR1 or the second direction DR2 and be spaced apart from an outer side of the frame opening F-OP of the mask frame MF by a predetermined distance.

Referring to FIGS. 4A and 4B, according to an embodiment of the mask frame MF, multiple first openings H1b may be disposed on one side of the bonding portion BP, e.g., in an upper side of the bonding portion BP with reference to FIG. 4B. In detail, the first openings H1b may be disposed between the second surface S2 of the mask frame MF and the bonding portion BP.

The first openings H1b may not overlap the bonding portion BP and may be spaced apart from the bonding portion BP. The first flow paths P1 may be spaced apart from the bonding portion BP by a predetermined distance. The first openings H1b may be disposed adjacent to the bonding portion BP so that the mask MK may be effectively adhered to the mask frame MF via the first flow paths P1 using the negative pressure generating part MPO.

The first openings H1b may be arranged in a line between the second surface S2 of the mask frame MF and the bonding portion BP, i.e., at one side of the bonding portion BP (e.g., in the upper side of the bonding portion BP with reference to FIG. 4B) along the second direction DR2.

The first openings H1b and the first flow paths P1 may be disposed with a certain pattern in the first direction DR1 or the second direction DR2. As an example, the first openings H1b may include first row openings arranged in the second direction DR2 and second row openings arranged in the second direction DR2 and spaced apart from the first row openings in the first direction DR1, and the second row openings may be shifted from the first row openings by a predetermined distance in the first direction and the second direction, however, this is merely an example. According to an embodiment, the first openings H1b may be arranged in two or more rows, the first openings H1b may be arranged in parallel in various ways along various directions without being limited to the first direction DR1 and the second direction DR2, and the first openings H1b may be arranged with no specific rules.

Referring to FIG. 5A, each first flow path P1 may include the first opening H1b and a second opening H2b in the mask frame MF. The first opening H1b may penetrate the first surface S1 and may extend in the third direction DR3. The first opening H1b may be spaced apart from the bonding portion BP by a predetermined distance. In detail, the first opening H1b may be disposed between the bonding portion BP and the second surface S2.

The second opening H2b may penetrate the second surface S2 and may extend in the second direction DR2. The second opening H2b may be coupled to the negative pressure generating part MPO. The first flow path P1 may extend from the negative pressure generating part MPO via the second opening H2b, and thus the mask MK may be tightly adhered to the mask frame MF. The negative pressure generating part MPO may be, for example, a vacuum pump, however, it should not be limited thereto or thereby. Various apparatuses that generate the negative pressures may be used as the negative pressure generating part MPO.

An air flow from the first opening H1b to the second opening H2b may be established in the first flow path P1 due to the negative pressure generated by the negative pressure generating part MPO. The mask MK may be adhered to the first surface S1 of the mask frame MF by the negative pressure formed in the first flow path P1. In addition, as the first opening H1b may be disposed adjacent to the bonding portion BP, impurities generated during a welding process may be collected by the first opening H1b. Accordingly, the impurities generated during the welding process may be readily removed through the first flow path P1, and thus, reliability and stability of the process may be improved.

The first flow path P1 according to the disclosure may include a first redirection portion CPb. The first redirection portion CPb may be disposed by the first opening H1b and the second opening H2b.

The first redirection portion CPb may denote a change in direction of the first flow path P1 and may have a shape selected from bent, curved, cornered and angled when viewed in a cross-section perpendicular to the first surface S1. A degree of the bending of the first redirection portion CPb may be defined as a bending degree between the second direction DR2 and the third direction DR3.

According to the disclosure, as the first flow path P1 includes the first redirection portion CPb, it may be difficult for the organic material to pass through the first flow path P1 during the deposition process, so defects in deposition quality occurring during an unintended deposition of the organic material passing through the first flow path P1 may be suppressed or prevented.

Referring to FIG. 5B, multiple rows of first openings H1b′ and H1b″ may be arranged parallel to each other in the second direction DR2 between a bonding portion BP and a second surface S2. Multiple rows of second openings H2b′ and H2b″ may also be arranged in the third direction DR3.

In detail, the first openings H1b′ and H1b″ may include a first opening H1b′ disposed adjacent to the bonding portion BP and a first opening H1b″ disposed adjacent to the first opening H1b′, and the first openings H1b′ and H1b″ may be disposed in parallel between the bonding portion BP and the second surface S2. The first openings H1b′ and H1b″ may respectively extend from corresponding second openings H2b′ and H2b″ to define multiple rows of first flow paths P1 respectively including first redirection portions CPb′ and CPb″.

According to the disclosure, as the multiple rows of first openings H1b′ and H1b″ may perforate the first surface S1, the first openings H1b′ and H1b″ and the first flow paths P1 may be broadly arranged in an area where the mask MK overlaps the mask frame MF. Accordingly, the mask MK may be uniformly adhered to the mask frame MF in the area where the mask MK overlaps the mask frame MF. Because there may be multiple rows of first flow paths P1, a suction force generated by the first flow paths P1 may increase, and thus the mask MK may be more effectively adhered to the mask frame MF.

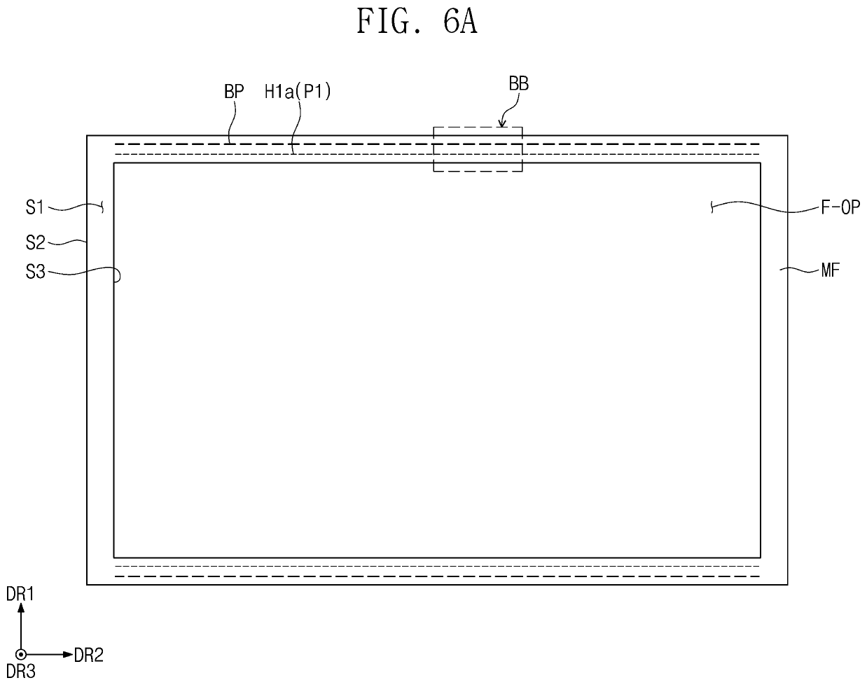

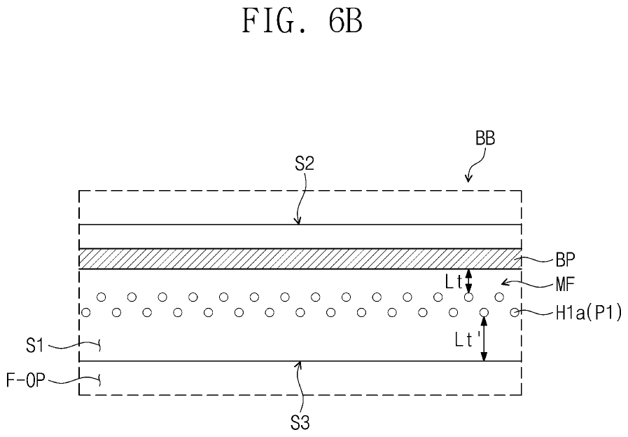

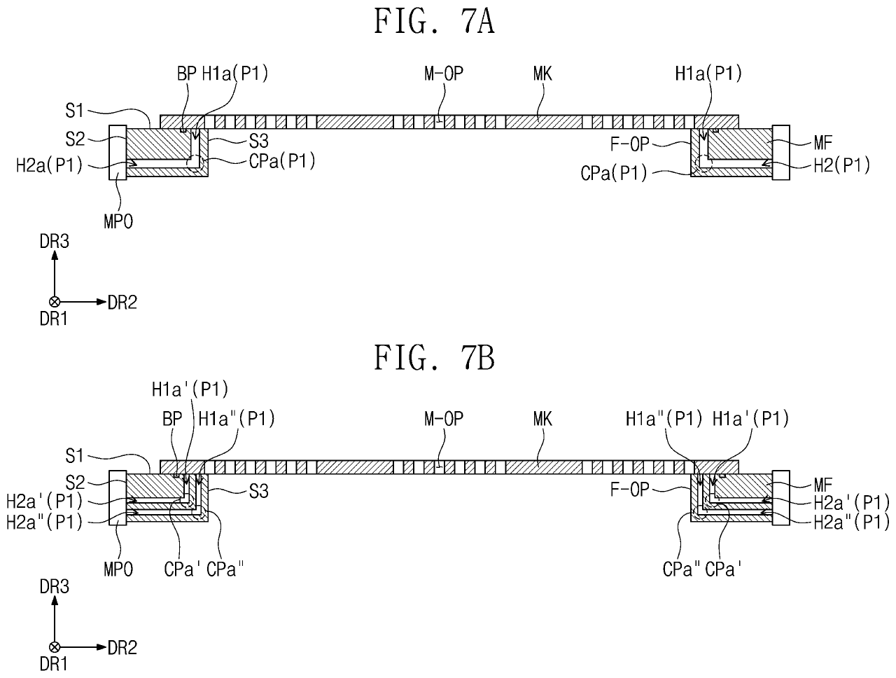

FIG. 6A is a plan view of a mask frame MF according to an embodiment of the disclosure, and FIG. 6B is an enlarged view of portion BB of the mask frame MF of FIG. 6A. FIGS. 7A and 7B are cross-sectional views of mask frames MF in a direction perpendicular to the first direction DR1 according to embodiments of the disclosure.

Referring to FIGS. 6A and 6B, multiple rows of first openings H1a may be disposed on first surface S1 of mask frame MF at one side of a bonding portion BP (e.g., a lower side of the bonding portion BP with reference to FIG. 6B) in the mask frame MF. In detail, the first openings H1a may be disposed between a frame opening F-OP of the mask frame MF and the bonding portion BP, that is between a third surface S3 and the bonding portion BP.

The first openings H1a disposed between the frame opening F-OP and the bonding portion BP may be disposed closer to the bonding portion BP than to the frame opening F-OP. A distance Lt between the first openings H1a and the bonding portion BP may be equal to or smaller than a distance Lt′ between the first openings H1a and the frame opening F-OP.

In a case where the mask MK may be adhered to the mask frame MF by a negative pressure generated by a negative pressure generating part MPO, the mask MK may be more effectively adhered to the mask frame MF by disposing the first openings H1a closer to the bonding portion BP.

Similar to the above descriptions, the first openings H1a may be arranged in two or more rows without being limited to the drawings, may be arranged parallel to each other with respect to various directions, or may be arranged with no specific rules.

Referring to FIG. 7A, the first openings H1a may be disposed between the frame opening F-OP and the bonding portion BP of the mask frame MF, and second openings H2a may penetrate a second surface S2, may extend in the second direction DR2, and may extend from the first opening H1a.

Referring to FIG. 7B, first openings H1a′ and H1a″ may include a row of first openings H1a′ disposed adjacent to a bonding portion BP and another row of first openings H1a″ disposed adjacent to the row of first openings H1a′, and the rows of first openings H1a′ and H1a″ may be disposed in parallel in the second direction DR2 between a frame opening F-OP of the mask frame MF and the bonding portion BP.

Multiple rows of second openings H2a′ and H2a″ may be disposed parallel to each other and are spaced-apart from each other in the third direction DR3 on second surface S2 of the mask frame MF. The first openings H1a′ and H1a″ may respectively extend from the second openings H2a′ and H2a″ respectively to define redirection portions CPa′ and CPa″ respectively to constitute multiple rows of first flow paths P1.

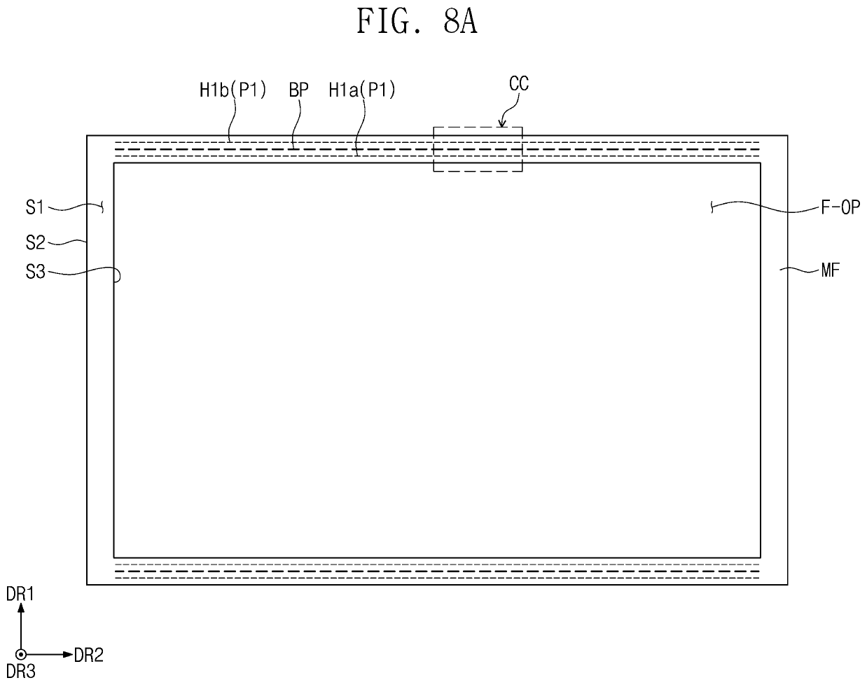

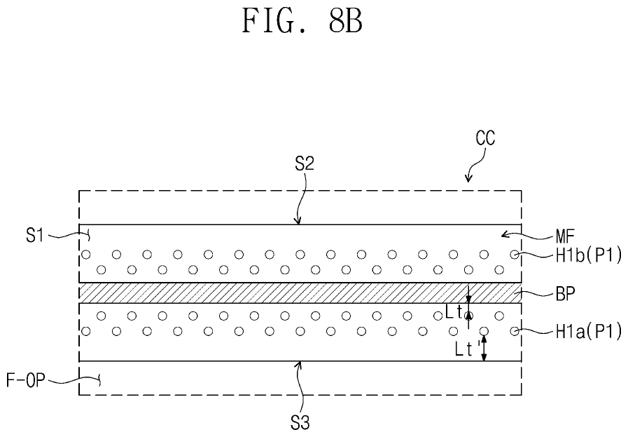

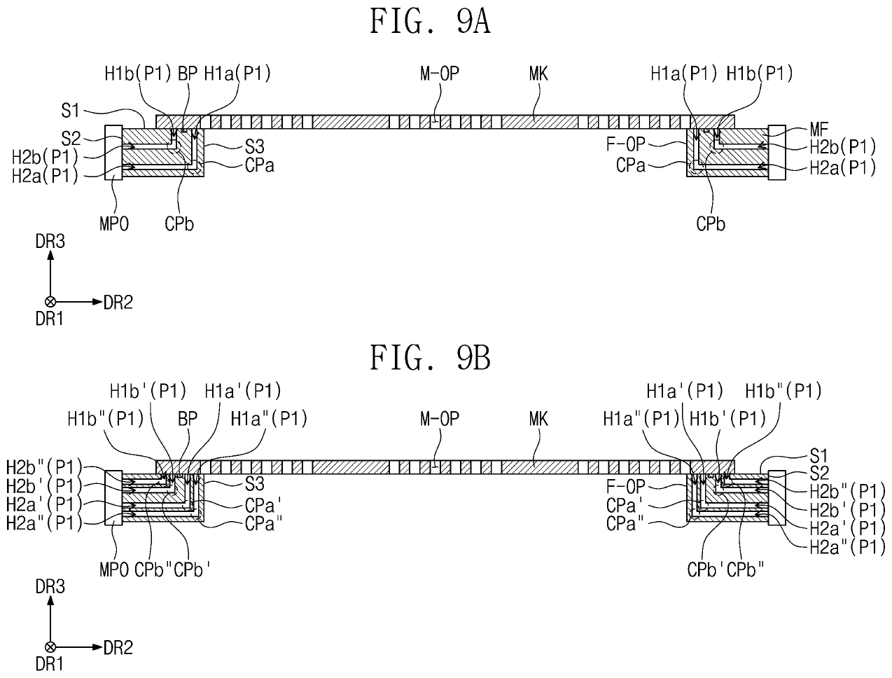

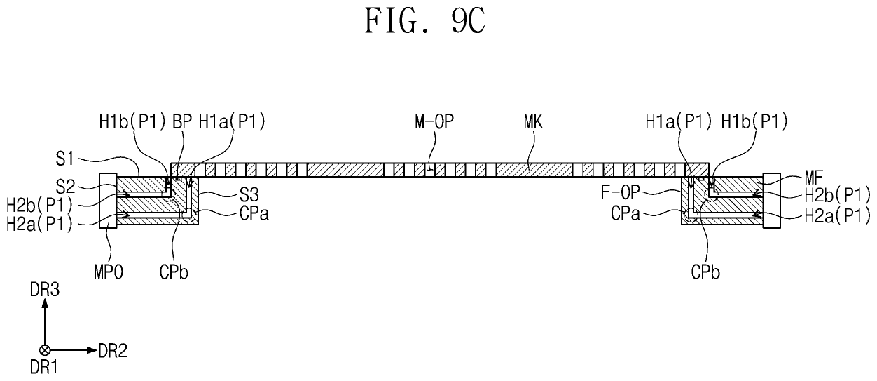

FIG. 8A is a plan view of a mask frame MF according to an embodiment of the disclosure, and FIG. 8B is an enlarged view of portion CC of the mask frame MF of FIG. 8A. FIGS. 9A to 9C are cross-sectional views of mask frames MF in a direction perpendicular to the first direction DR1 according to embodiments of the disclosure.

Referring to the mask frame MF of FIGS. 8A and 8B, multiple rows of first openings H1b may be disposed on a side (an upper side in FIG. 8B) of a bonding portion BP, and multiple rows of first openings H1a may be disposed on another side (a lower side in FIG. 8B) of the bonding portion BP. In detail, the first openings H1b may be disposed between a second surface S2 and the bonding portion BP of the mask frame MF. The first openings H1a may be disposed between a third surface S3 and the bonding portion BP of the mask frame MF, i.e., between a frame opening F-OP and the bonding portion BP of the mask frame MF. As a result, the bonding portion BP may be disposed between ones of multiple rows of first flow paths P1.

Since the bonding portion BP may be disposed between the rows of first flow paths P1, a negative pressure generating part MPO may generate a negative pressure in the first flow paths P1 at both sides of the bonding portion BP, and thus, the mask MK may be effectively adhered to first surface S1 of the mask frame MF.

The first openings H1a and H1b may be disposed adjacent to the bonding portion BP. As an example, the first openings H1a disposed between the frame opening F-OP and the bonding portion BP of the mask frame MF may be disposed closer to the bonding portion BP than to the frame opening F-OP. A distance Lt between the first openings H1a and the bonding portion BP may be equal to or smaller than a distance Lt′ between the first openings H1a and the frame opening F-OP. The first openings H1b disposed between the second surface S2 and the bonding portion BP of the mask frame MF may be also disposed closer to the bonding portion BP.

Similar to the above descriptions, the first openings H1a and H1b may be arranged in two or more rows without being limited to the drawings, may be arranged parallel to each other with respect to various directions, or may be arranged with no specific rules.

Referring to FIG. 9A, the first openings H1a may be disposed between the frame opening F-OP and the bonding portion BP of the mask frame MF. The first openings H1b may be disposed between the second surface S2 and the bonding portion BP of the mask frame MF. Second openings H2a and H2b may penetrate the second surface S2, may extend in the second direction DR2, and may respectively extend from the first openings H1a and H1b. Each of the first flow paths P1 may include the first openings H1a and H1b, the second openings H2a and H2b extend from the first openings H1a and H1b, and first redirection portions CPa and CPb respectively.

Referring to FIG. 9B, each of rows of first openings H1a′ and H1a″ disposed between a frame opening F-OP and a bonding portion BP of the mask frame MF and rows of second openings H1b′ and H1b″ disposed between a second surface S2 and the bonding portion BP may be arranged parallel to each other in the second direction DR2 or a direction opposite to the second direction DR2.

Second openings H2a′, H2a″, H2b′, and H2b″ may be arranged parallel to each other on the second surface S2 of the mask frame MF along the third direction DR3 or the direction opposite to the third direction DR3.

The first openings H1a′, H1a″, H1b′, and H1b″ may respectively extend from the second openings H2a′, H2a″, H2b′, and H2b″ to define rows of first flow paths P1 that include first redirection portion CPa′, CPa″, CPb′, and CPb″ respectively.

Referring to FIG. 9C, a first openings H1b disposed between a second surface S2 and a bonding portion BP of the mask frame MF may not overlap a mask MK. The first opening H1b perforating the first surface S1 may extend from a second opening H2b perforating the second surface S2 in a direction different from an extension direction of the first opening H1b to define a first flow path P1. The first flow path P1 may include a first redirection portion CPb defined by the first opening H1b and the second opening H2b that extends from the first opening H1b. The first redirection portion CPb may have a shape selected from bent, curved, cornered and angled in a cross-section perpendicular to the first surface S1, and thus, defects in deposition quality (i.e. deposition occurring at locations not originally designed) attributed to deposition material DM or the organic material passing through the first flow path P1 may be prevented.

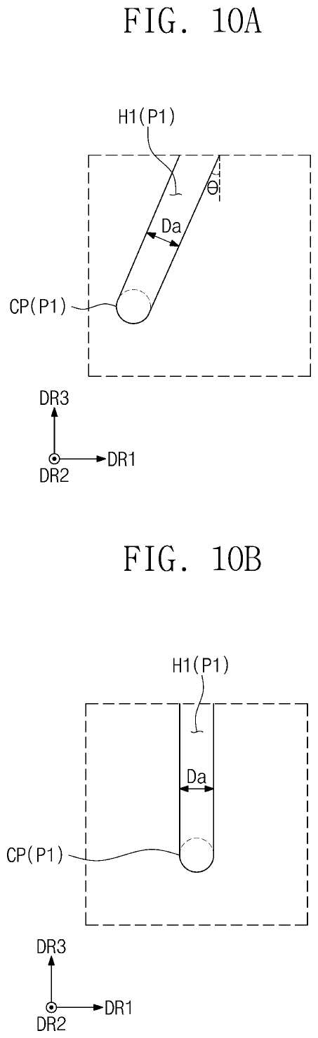

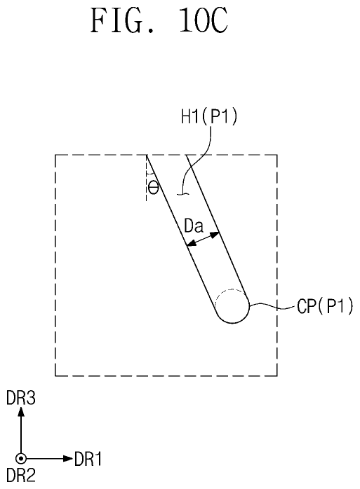

FIGS. 10A to 10C are cross-sectional views of a portion of mask frame to show a first flow path P1 in a direction perpendicular to the second direction according to embodiments of the disclosure.

Referring to FIGS. 10A to 10C, a first opening H1 may extend in a direction that forms a predetermined angle θ with respect to the third direction DR3 without being limited to extending merely in the third direction DR3.

Referring to FIG. 10A, the first opening H1 may be inclined in a direction opposite to the first direction DR1 (a left side with reference to FIG. 10A), and in detail, the first opening H1 may extend in a direction that forms the predetermined angle θ with respect to the third direction DR3. Referring to FIG. 10B, a first opening H1 may extend in the third direction DR3. Referring to FIG. 10C, a first opening H1 may be inclined to the first direction DR1 and may extend in a direction that forms the predetermined angle θ with respect to the third direction DR3.

As the first opening H1 extends in the direction that forms the predetermined angle θ with respect to the third direction DR3, it may be difficult for an organic material to pass through a first flow path P1 during the deposition process, so defects in deposition quality occurring when the organic material may be deposited different from originally designed may be suppressed.

The first flow path P1 may have a section diameter that may be inversely proportional to an intensity of a negative pressure formed in the first flow path P1. The section diameter Da of the first opening H1 may be about 0.2 mm or less, and thus, a mask MK may be prevented from being deformed due to the negative pressure formed in the first flow path P1. The section diameter Da of the first flow path P1 may be a same as a section diameter of the first opening H1.

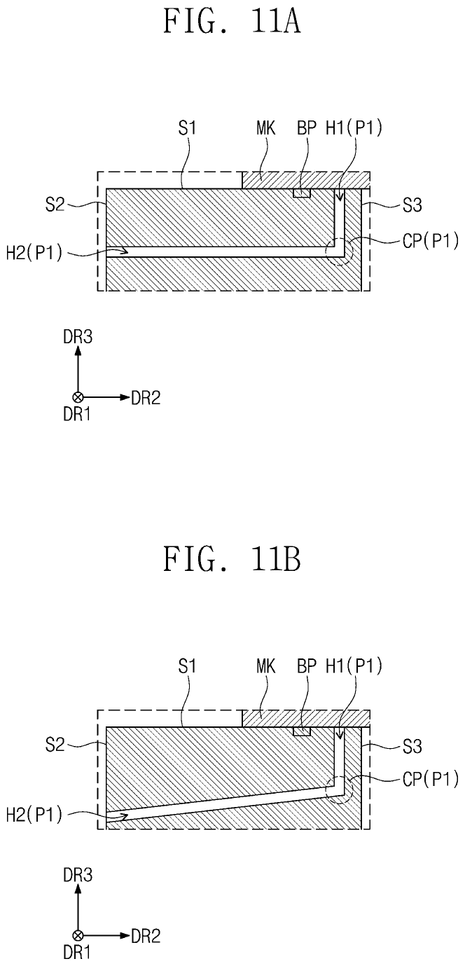

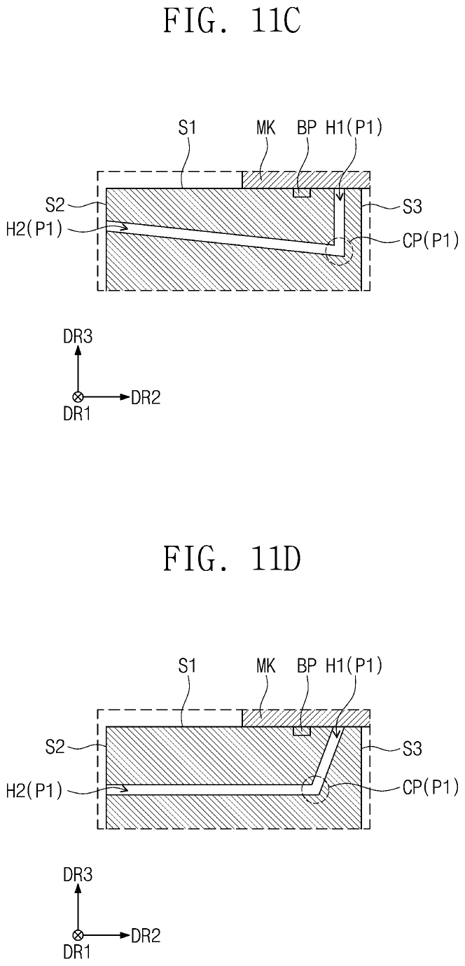

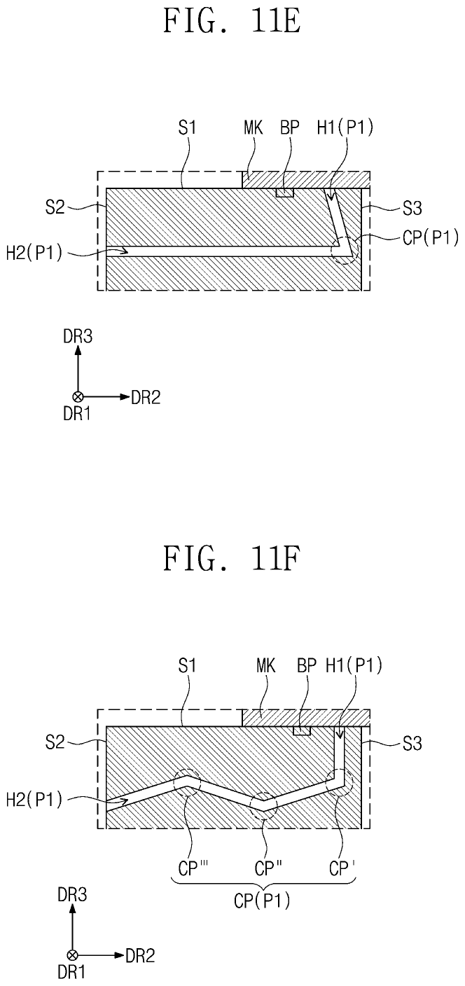

FIGS. 11A to 11F are cross-sectional views of a mask frame to show a first flow path P1 in a direction perpendicular to the first direction DR1 according to embodiments of the disclosure.

Referring to FIGS. 11A to 11E, a first opening H1 may extend in the direction opposite to the third direction DR3 while being slightly inclined with respect to the second direction DR2 from the first surface S1 that may be in contact with a mask MK, and a second opening H2 may extend in the second direction DR2 or the direction opposite to the second direction DR2 while being slightly inclined in the third direction DR3 or the direction opposite to the third direction DR3 from the second surface S2. Stated another way, the first opening H1 may be inclined so as not to be parallel to the second surface S2 or a third surface S3 while extending, and the second opening H2 may be inclined so as not to be parallel to the first surface S1 while extending.

Referring to FIG. 11A, the second opening H2 perforating the second surface S2 may extend in the second direction DR2. An angle between the first opening H1 and the second opening H2 may be a right angle. Referring to FIG. 11B, the second opening H2 may extend in the second direction DR2 or the direction opposite to the second direction DR2 while being slightly inclined in the direction opposite to the third direction DR3. FIG. 11B shows an angle between the first opening H1 and the second opening H2 to be an obtuse angle.

Referring to FIG. 11C, the second opening H2 may extend in the second direction DR2 or in the direction opposite to the second direction DR2 while being slightly inclined with respect to the third direction DR3. An angle between the first opening H1 and the second opening H2 may be an acute angle. As the angle between the first opening H1 and the second opening H2 may be the acute angle, it may be difficult for the organic material to pass through the first flow path P1 during the deposition process, so that defects in deposition quality occurring when the organic material may be deposited different from originally designed may be suppressed.

Referring to FIG. 11D, the first opening H1 perforating the first surface S1 may extend in the direction opposite to the third direction DR3, i.e., a direction toward a lower side of FIG. 11D, while being slightly inclined with respect to a negative second direction (i.e., −DR2), i.e., a direction toward a left side of FIG. 11D. An angle between the first opening H1 and the second opening H2 may be an obtuse angle.

Referring to FIG. 11E, the first opening H1 may extend in the direction opposite to the third direction DR3, i.e., a direction toward a lower side of FIG. 11E, while being slightly inclined with respect to the second direction DR2. An angle between the first opening H1 and the second opening H2 may be an acute angle.

The extension direction of the first opening H1 and the second opening H2 should not be limited to those shown in FIGS. 11A to 11E, as the first opening H1 and the second opening H2 may extend in other various directions and still be within the scope of this disclosure.

The first flow path P1 may include a first redirection portion CP disposed where the first opening H1 extends from the second opening H2, and the first redirection portion CP may have a curved, cornered, angled or bent shape when viewed in a cross-section perpendicular to the first surface S1. As shown in FIG. 11F, the bent shape of the first redirection portion CP may include multiple curves.

Referring to FIG. 11F, the first redirection portion CP may include multiple curves CP′, CP″, and CP′″. As the first redirection portion CP includes the curves CP′, CP″, and CP′″, it may be difficult for the organic material to pass through the first flow path P1 during the deposition process, so that quality defects in deposition that typically occur when the organic material may be deposited at locations different from originally designed may be suppressed. The shape and the number of the curves CP′, CP″, and CP′″ should not be limited to those shown in FIG. 11F.

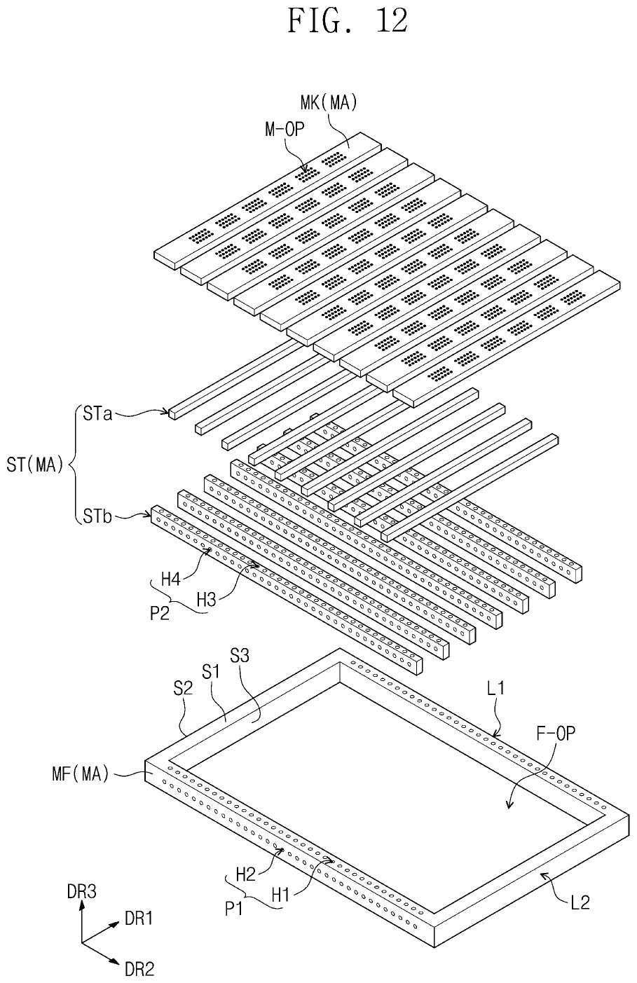

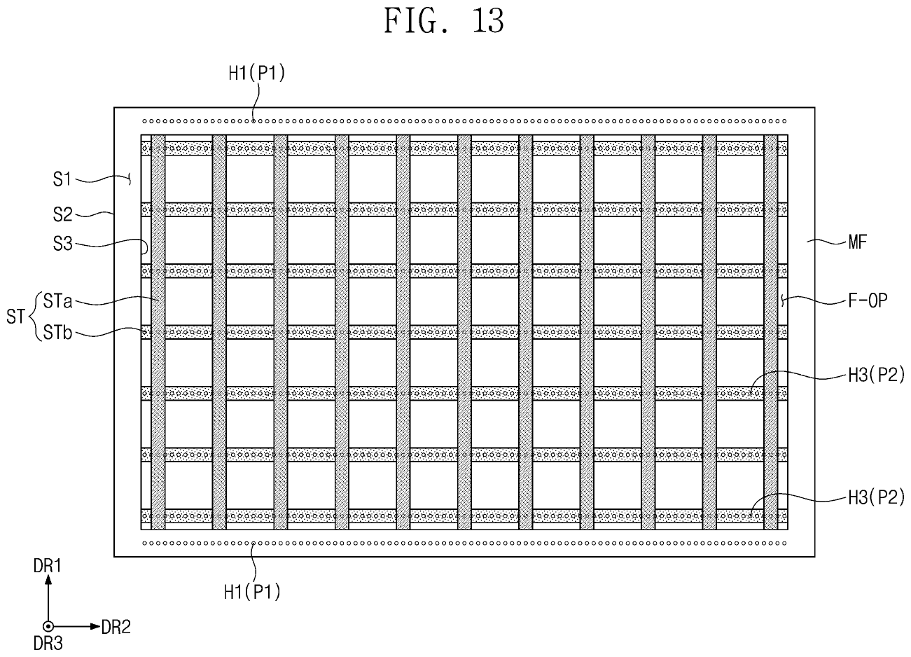

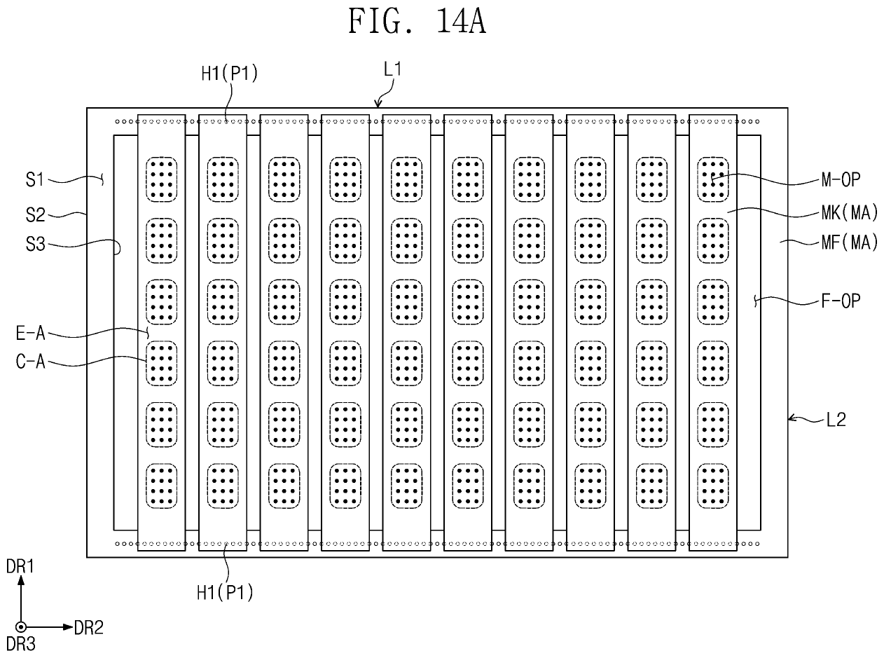

FIG. 12 is an exploded perspective view of a mask assembly MA according to an embodiment of the disclosure, and FIG. 13 is a plan view of the mask assembly MA according to an embodiment of the disclosure.

In describing the mask assembly MA of the disclosure, components having a same shape or performing a same function as those described above may be assigned with same reference numerals, and detailed descriptions of same components may be omitted.

Referring to FIGS. 12 and 13, a second flow path P2 may be disposed within a support stick ST of the mask assembly MA. As shown in FIGS. 12 and 13, the second flow path P2 may be within a second stick STb, however, it should not be limited thereto or thereby.

The second flow path P2 may extend from a negative pressure generating part MPO to allow a mask MK to be adhered to the support stick ST. Similar to a first flow path P1, the second flow path P2 may allow the mask MK to be adhered the support stick ST so that a contact failure between the mask MK and the support stick ST may be prevented, and thus, a deposition accuracy of a deposition material DM on a substrate may be improved.

The second flow path P2 may include a second redirection portion (not shown) having a shape selected from curved, cornered, angled or bent when viewed in a cross-section perpendicular to a surface facing the mask MK. The second flow path P2 may include a third opening H3 disposed in the surface facing the mask MK and extending in a first direction and a fourth opening H4 disposed in a surface facing the negative pressure generating part MPO and extending in a second direction different from the first direction.

There may be multiple second flow paths, and consequently, there may be multiple third openings H3 and fourth openings H4. The third openings H3 and the fourth openings H4 may be disposed in the first direction DR1 or the second direction DR2 to have a uniform pattern, however, according to an embodiment, the third openings H3 and the fourth openings H4 may be randomly arranged.

According to the mask assembly, the first flow path P1 may be disposed within the mask frame MF, and the second flow path P2 may be disposed within the support stick ST. Accordingly, the mask MK may be adhered to the mask frame MF and/or the support stick ST using the negative pressure generating part MPO. Therefore, the contact failure between the mask MK and the support stick ST and/or the mask frame MF may be effectively prevented, and the deposition accuracy of the deposition material DM on the substrate may be improved.

Hereinafter, a method of manufacturing the mask assembly MA according to an embodiment of the disclosure will be described. In describing the manufacturing method of the mask assembly MA, components having a same shape or performing a same function as those described above may be assigned with the same reference numerals, and detailed descriptions of the same components may be omitted.

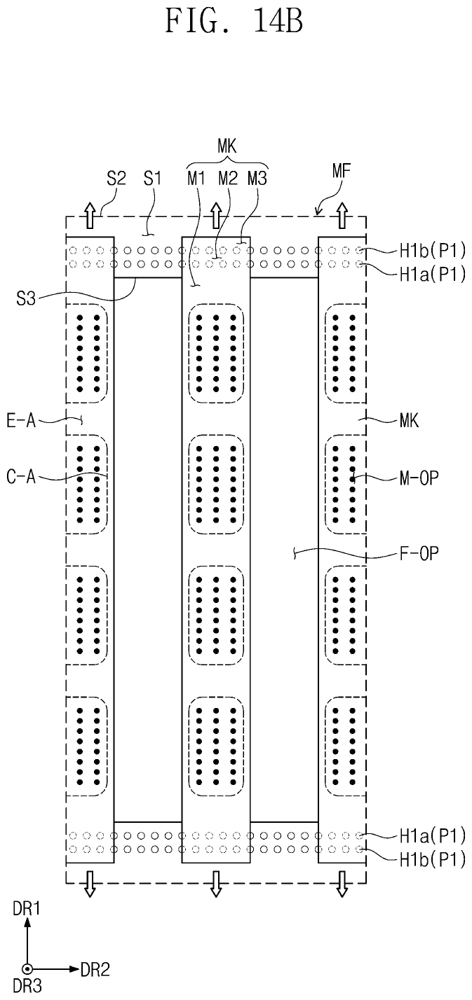

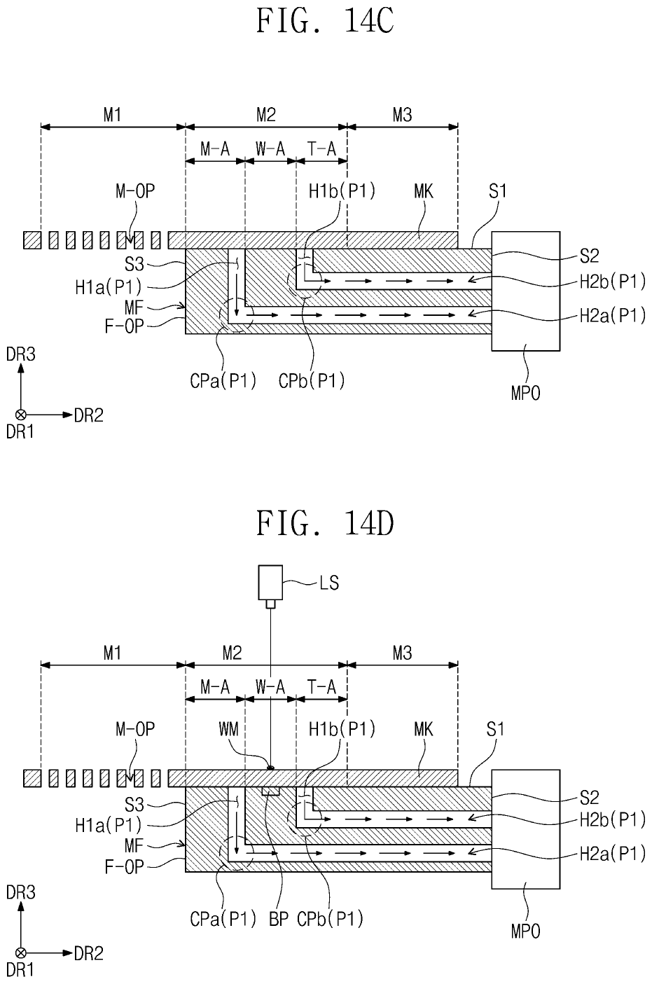

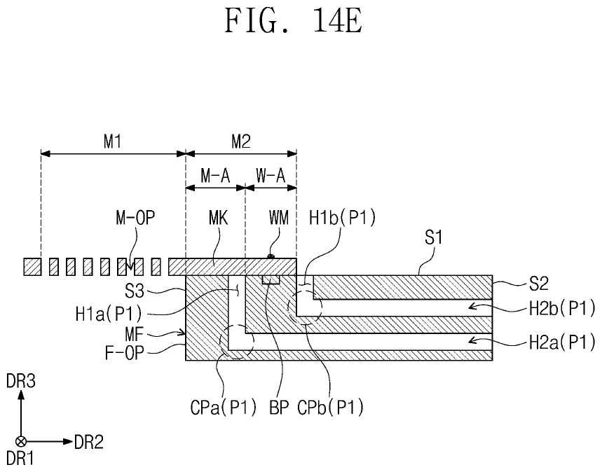

FIGS. 14A to 14E are views of a method of manufacturing a mask assembly MA according to an embodiment of the disclosure. FIGS. 14A and 14B are plan views of some processes, and FIGS. 14C to 14E are schematic cross-sectional views of some processes.

Referring to FIG. 14A, the mask MK may be disposed on the mask frame MF. The mask frame MF may be provided with the frame opening F-OP disposed therethrough, and the mask MK may include the cell areas C-A overlapping the frame opening F-OP.

The mask frame MF may include the first flow path P1 that includes the first opening H1 and the second opening H2. The first opening H1 and/or the second opening H2 may be formed by a laser-drilling technique using a laser device, however, they should not be limited thereto or thereby. The first opening H1 and the second opening H2 may instead be formed using various other devices.

Meanwhile, although not shown in figures, the support sticks ST may be disposed on the mask frame MF prior to the disposing of the mask MK on the mask frame MF and then the mask MK may be disposed on the support sticks ST. The support sticks ST may be bonded to the mask frame MF by a welding technique, however the bonding technique between the support sticks ST and the mask frame MF should not be limited.

There may be multiple masks MK to a single mask frame MF and a single mask assembly MA, and the masks MK may be arranged adjacent to each other or spaced apart from each other along the mask frame MF.

The mask MK may be tensioned prior to the disposing of the mask MK on the mask frame MF. According to the tensioning of the mask MK, the mask MK may be tensioned in a direction parallel to the first direction DR1 and/or the second direction DR2 away from a center of the mask MK by a clamp included in a tensioner. In detail, a third area M3 described later may be tensioned in the tensioning of the mask MK to align the frame opening F-OP with the cell area C-A.

After the tensioning of the mask MK, the mask MK may be adhered to the mask frame MF. The adhering of the mask MK to the mask frame MF may be performed prior to the bonding of the mask MK to the mask frame MF.

Referring to FIGS. 14B and 14C, the mask MK may include a first area M1 corresponding to the frame opening F-OP, the first area M1 of mask MK including mask openings M-OP disposed therein, a second area M2 adjacent to the first area M1, and the third area M3 spaced apart from the first area M1 by the second area M2 disposed therebetween. The third area M3 may be gripped by the clamp, and the second area M2 may be supported by the mask frame MF.

The second area M2 of the mask MK may include a margin area M-A, a bonding area W-A, and a trimming area T-A, which may be sequentially arranged in order from the closest to the farthest from the mask openings M-OP.

The bonding area W-A of mask MK may be disposed at a location corresponding to the bonding portion BP of the mask frame MF, the bonding portion BP being a portion of the mask frame MF, that gets bonded to the mask MK.

In detail, the bonding area W-A is a portion of the peripheral area E-A of the mask MK that may be bonded to the mask frame MF. The bonding area W-A may extend in the first direction DR1 or the second direction DR2 to correspond to the bonding portion BP of mask frame MF.

The bonding portion BP of mask frame MF and the bonding area W-A of mask MK may be attached by the welding technique. The mask MK may be bonded to the mask frame MF by melting a welding stick disposed on the mask MK. Welding protrusions WM may be formed on the upper surface of the mask MK at a location that overlaps the bonding portion BP and the bonding area W-A.

The first opening H1 perforating the first surface S1 of the mask frame MF may be formed at a location corresponding to at least one of the margin area M-A and the trimming area T-A. That is, the first opening H1 of the first flow path P1 may overlap the margin area M-A and/or the trimming area T-A. Specifically, in case that the first openings H1 are formed on both sides of the bonding portion BP of the mask frame MF, the first openings H1 formed between the frame opening F-OP and the bonding portion BP may overlap the margin area M-A, and the first openings H1 between bonding portion BP and the second surface S2 may overlap the trimming area T-A or both the trimming area T-A and the third area M3.

In the adhering of the mask MK to the mask frame MF, the first opening H1 of the first flow path P1 may be adhered to the mask MK, the second opening H2 may be adhered to the negative pressure generating part MPO, and thus a negative pressure may be formed in the mask MK adjacent to the first opening H1. The mask MK may be adhered to the mask frame MF by the negative pressure formed in the first flow path P1.

Because the mask MK is adhered to the mask frame MF, a bonding defect, e.g., a welding defect, may be prevented from occurring in a process of bonding the mask MK to the mask frame MF to be described later.

Referring to FIGS. 14D and 14E, the manufacturing method of the mask assembly MA may further include the bonding of the mask MK to the mask frame MF and removing the trimming area T-A and the third area M3 of mask MK.

In the bonding of the mask MK to the mask frame MF, a welding process to weld the mask MK to the mask frame MF may be carried out. When the mask MK and the mask frame MF are welded to each other, the welding process may be performed on the mask MK after the frame opening F-OP is aligned with the mask openings M-OP. In detail, a welding stick may be disposed on a portion of the peripheral area E-A where the mask MK that overlaps the mask frame MF. The welding stick may have a bar shape extending in a direction. A laser beam may be irradiated onto the welding stick using a laser device LS to melt the welding stick, and the melted welding stick may allow the mask MK to be bonded to a portion of an upper surface of the mask frame MF that is in contact with the mask MK. The mask MK may be bonded to the mask frame MF by the melted welding stick. When the mask MK is bonded to the mask frame MF, the bonded portion of mask MK may be the bonding area W-A, and the bonded portion of the mask frame MF may be the bonding portion BP. The bonding area W-A of the mask and the bonding portion BP of the mask frame MF may include a metal oxide.

The welding protrusions WM may be formed on the upper surface of the mask MK overlapping the bonding portion BP of the mask frame MF by the welding process. When the welding process is carried out, the negative pressure generating part MPO may be used to continuously generate the negative pressure in the first flow path P1.

According to the manufacturing method of the mask assembly MA, as the negative pressure may be formed in the first flow path P1 before or during the bonding of the mask MK to the mask frame MF, the adhesion between the mask MK and the mask frame MF may increase. Accordingly, the deposition accuracy of the mask assembly MA may be improved. In addition, since a process such as physically pressing the mask MK using a jig is not required, a process of managing a flatness of the bonding area W-A of mask MK may not be needed. Thus, the manufacturing method of the mask assembly MA may be simplified.

The removing of the trimming area T-A and the third area M3 of mask MK may be performed by irradiating a laser beam onto the trimming area T-A and third area M3 of the mask MK using a laser irradiation device. Accordingly, the completed mask assembly MA of FIG. 14E may include only the first area M1, the margin area M-A, and the bonding area W-A of the second area M2. Various other devices that remove the trimming area T-A and the third area M3 may instead be used instead of the laser irradiation device.

The first opening H1 disposed within the mask frame MF may overlap or may not overlap the mask MK after the removal of the edge portions of mask MK. Although the first flow path P1 in which the first opening H1 may be disposed may be provided in an area that does not overlap the mask MK (e.g., the area overlapping the third area M3 or the trimming area T-A), the deposition material DM or the organic material may still be prevented from being deposited on the substrate or the chamber CHB after passing through the first flow path P1 during the deposition process by forming the redirection portion CP in the first flow path P1 or by adjusting the angle between the first opening H1 and the second opening H2 to be greater than zero (0) degrees and equal to and smaller than about 90 degrees. Accordingly, unwanted and unintended deposition material DM may be prevented from being deposited on the substrate or the chamber CHB, and thus deterioration in quality of the product may be suppressed.

According to the mask assembly MA, the gap between the mask frame MF and the mask MK may be reduced due to the flow path P1 formed in the mask frame MF, and thus the mask frame MF may be adhered to the mask MK. In addition, the flow path P1 formed in the mask frame MF may include at least one redirection portion CP, and thus the substrate may be prevented from being contaminated due to the organic material entering the flow path P1 during the deposition process. In addition, since the mask MK may be bonded to the mask frame MF, contact failure between the mask frame MF and the mask MK may be prevented, and the deposition accuracy of the deposition material DM on the substrate may be improved.

Although the embodiments of the disclosure have been described, it is understood that the disclosure should not be limited to these embodiments but various changes and modifications can be made by one ordinary skilled in the art within the spirit and scope of the disclosure as hereinafter claimed. Therefore, the disclosed subject matter should not be limited to any single embodiment described herein, and the scope of the inventive concept shall be determined according to the adhered claims.

What is claimed is:

1. A mask frame comprising:
a first surface facing a mask;
a second surface extending from a side of the first surface at an angle;
a third surface extending from another side of the first surface at an angle to define a frame opening; and
a first flow path comprising a first opening and a second opening extending from the first opening, the first opening defined through the first surface and extending in a first direction, the second opening defined through the second surface and extending in a second direction different from the first direction.

2. The mask frame of claim 1, wherein
the first flow path further comprises a first redirection portion defined by the first opening and the second opening, and
the first redirection portion having a shape in a cross-section perpendicular to the first surface, the shape being selected from bent, curved, cornered, and angled.

3. The mask frame of claim 2, wherein the shape comprises a plurality of curves.

4. The mask frame of claim 2, further comprising a bonding portion bonded to the mask, and the bonding portion being spaced apart from the first flow path by a predetermined distance.

5. The mask frame of claim 4, wherein the first opening is defined between the frame opening and the bonding portion when viewed in a plane parallel to the first surface and is disposed closer to the bonding portion than the frame opening.

6. The mask frame of claim 4, wherein
the mask frame comprises a plurality of rows of first flow paths, and
the bonding portion is disposed between ones of the rows of the first flow paths.

7. The mask frame of claim 1, wherein the first flow path has a section diameter equal to or smaller than about 0.2 mm.

8. A mask assembly comprising:
a mask frame comprising a frame opening and a first flow path, the first flow path extending through the mask frame; a mask disposed on the mask frame, and
a negative pressure generating part, the first flow path connected to the negative pressure generating part to allow the mask to be adhered to the mask frame,
wherein the first flow path comprises a first redirection portion having a first shape in a cross-section perpendicular to a surface facing the mask, the first shape being selected from bent, curved, cornered, and angled.

9. The mask assembly of claim 8, wherein the first shape comprises a plurality of curves.

10. The mask assembly of claim 8, wherein the first flow path further comprises:
a first opening extending in a first direction from a first surface of the mask frame that faces the mask; and
a second opening extending in a second and different direction from a second surface of the mask frame that faces the negative pressure generating part, the second opening extending from the first opening.

11. The mask assembly of claim 10, wherein an angle between the first opening and the second opening is greater than about zero (0) degrees and equal to or less than about 90 degrees.

12. The mask assembly of claim 10, wherein the mask frame further comprises a bonding portion bonded to the mask, the bonding portion being spaced apart from the first flow path by a predetermined distance.

13. The mask assembly of claim 12, wherein the first opening is defined between the frame opening and the bonding portion and is disposed closer to the bonding portion than the frame opening.

14. The mask frame of claim 12, wherein the mask frame comprises a plurality of rows of first flow paths, the bonding portion being disposed between ones of the rows of the first flow paths.

15. The mask assembly of claim 8, further comprising a plurality of support sticks disposed on the mask frame.

16. The mask assembly of claim 15, wherein the support sticks comprise a second flow path connected to the negative pressure generating part to adhere the mask to the support sticks, the second flow path comprising a second redirection portion having a second shape in a cross-section perpendicular to the surface facing the mask, the second shape being selected from bent, curved, cornered and angled.

17. A method of manufacturing a mask assembly, comprising:
providing a mask frame comprising a frame opening and a first flow path, the first flow path being spaced-apart from the frame opening;
providing a mask;
placing the mask on the mask frame;
adhering the mask to the mask frame by providing a negative pressure to the first flow path; and
bonding the mask to the mask frame.

18. The method of claim 17, further comprising tensioning a third area, wherein the mask comprises a first area, a second area, and the third area, and
wherein the first area comprises a plurality of cell areas and corresponds to the frame opening, the second area being disposed adjacent to the first area and between the first area and the third area, the frame opening being aligned with the cell areas upon the tensioning of the third area.

19. The method of claim 18, wherein the second area comprises a margin area, a bonding area, and a trimming area sequentially arranged in an order from a closest to a farthest from the frame opening and the cell areas, a first opening of the first flow path being disposed at a location corresponding to at least one of the margin area and the trimming area.

20. The method of claim 19, further comprising removing the trimming area and the third area after the bonding of the mask to the mask frame.
